(19) United States
(12) Patent Application Publication
(10) Pub. No.: US 2013/0137208 A1
(43) Pub. Date: May 30, 2013

(54) METHOD FOR MANUFACTURING SOLAR CELL MODULE

(71) Applicants: Woo-Seok CHEONG, Daejeon (KR); Rae-Man Park, Yuseong-gu (KR)

(72) Inventors: Woo-Seok CHEONG, Daejeon (KR); Rae-Man Park, Yuseong-gu (KR)

(73) Assignee: ELECTRONICS AND TELECOMMUNICATIONS RESEARCH INSTITUTE, Daejeon (KR)

(21) Appl. No.: 13/617,465

(22) Filed: Sep. 14, 2012

(30) Foreign Application Priority Data
Nov. 29, 2011 (KR) 10-2011-0126267

(51) Int. Cl. H01L 31/18

(52) U.S. Cl. 438/95; 257/E31.015

(57) ABSTRACT

Provided is a method of manufacturing a solar cell module The method includes: forming a bottom electrode layer on a substrate; forming a light absorbing layer on the bottom electrode layer and the substrate; forming a first trench that exposes the bottom electrode layer by patterning the light absorbing layer; and forming a window electrode layer that extends from the top of the light absorbing layer to the bottom of the bottom of the first trench, wherein the window electrode layer is formed through an ionized physical vapor deposition method.

### CROSS-REFERENCE TO RELATED APPLICATIONS

This U.S. non-provisional patent application claims priority under 35 U.S.C. §119 of Korean Patent Application No. 10-2011-0126267, filed on Nov. 29, 2011, the entire contents of which are hereby incorporated by reference.

### BACKGROUND OF THE INVENTION

The present invention disclosed herein relates to a method of manufacturing a solar cell, and more particularly, to a method of manufacturing a solar cell module.

A Copper Indium Gallium Selenide (CIGS) thin film solar cell, which attracts a lat of attention recently, has higher efficiency than an amorphous silicon solar cell and relatively high stability such as no initial degradation. Thus, the CIGS thin film solar cell is now in development for commercialization. Additionally, the CIGS thin film solar cell has properties as excellent as a lightweight high-efficient solar cell for space, which could replace a typical single crystal silicon solar cell, is studied first. That is, its power generation amount per unit weight is about 100 W/kg, which is far more excellent than about 20 W/kg to about 40 W/kg of a typical silicon or GaAs solar cell. Since its power generation amount reaches about 20.3% in a current single junction structure, the CIGS thin film solar cell has an almost equal maximum high efficiency to a typical single crystal silicon solar cell.

Despite those advantages, the CIGS thin film solar cell has low productivity. The reason is that since the CIGS thin film solar cell module is completely manufactured typically after undergoing various stages of a vacuum process, manufacturing costs are high due to large investment on equipment and mass productivity is low. The CIGS thin film solar cell module includes a bottom electrode, a light absorbing layer, and a window electrode layer, all of which are stacked on a substrate. The window electrode layer may include a transparent electrode layer having a thickness of several μm to tens of μm. The window electrode layer may be formed through a physical vapor deposition method or a chemical vapor deposition method.

However, due to a low step coverage of the window electrode layer, the physical vapor deposition method may cause electrical contact defects at a sidewall of a trench that separates light absorbing layers. As a result, its production yield is decreased. When a window electrode layer is formed with a thickness of more than about 3 μm in order to resolve such an issue, the time consumed for a deposition process becomes longer and the amount of targets consumed is increased. Therefore, its productivity is decreased. Furthermore, since the window electrode layer formed through the chemical vapor deposition method may contain a large amount of impurities, its electrical conductivity is low. Therefore, the window electrode layer is required to be formed with a thickness of more than about 3 μm through the chemical vapor deposition method.

Accordingly, when a typical method for manufacturing a window electrode of a solar cell module is used, a physical deposition or chemical deposition method may reduce its yield and productivity.

### SUMMARY OF THE INVENTION

The present invention provides a solar cell module that increases or maximizes production yield and productivity, and a method of manufacturing the same.

Embodiments of the present invention provide a method of manufacturing a solar cell module, the method including: forming a bottom electrode layer on a substrate; forming a light absorbing layer on the bottom electrode layer and the substrate; forming a first trench that exposes the bottom electrode layer by patterning the light absorbing layer; and forming a window electrode layer that extends from the top of the light absorbing layer to the bottom of the bottom of the first trench, wherein the window electrode layer is formed through an ionized physical vapor deposition method.

In some embodiments, the window electrode layer may include zinc oxide.

In other embodiments, the zinc oxide may further include at least one conductive impurity of boron, gallium, aluminum, magnesium, indium, tin, and fluoride.

In still other embodiments, the window electrode layer may include indium tin oxide.

In even other embodiments, the window electrode layer may have a thickness of about 0.1 μm to about 1.5 μm, and may have a step coverage of more than about 20% at the bottom and sidewall of the first trench.

In yet other embodiments, the ionized physical vapor deposition method may use a first plasma of inert gas that sputters deposition particles of the window electrode layer from a target and a second plasma that increases an ionization rate of the inert gas.

In further embodiments, the first plasma may be induced from a sputter gun below the substrate, and the second plasma may be induced from inductively coupled plasma tubes between the sputter gun and the substrate.

In still further embodiments, the forming of the light absorbing layer further may include forming a buffer layer on the light absorbing layer.

In even further embodiments, the buffer layer may include cadmium sulfide.

In yet further embodiments, the light absorbing may include a chalcopyrite compound semiconductor of Copper Indium Gallium Selenide (CIGS).

In yet further embodiments, the bottom electrode layer may include molybdenum.

In yet further embodiments, the method may further include separating cells by using a second trench that exposed the bottom electrode layer, the second trench being formed by removing the window electrode layer and the light absorbing layer adjacent to the first trench.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a perspective view illustrating a solar cell module according to an embodiment of the present invention;

FIGS. 2 to 6 are sectional views taken along the line I-I′ of FIG. 1 illustrating a method of manufacturing a solar cell module according to an embodiment of the present invention;

FIG. 7 is a sectional view illustrating an ionized physical vapor deposition apparatus for forming a window electrode layer;

FIGS. 8 and 9 are sectional views illustrating respective second and third window electrode layers formed through a physical vapor deposition method and a chemical vapor deposition method;

FIG. 10 is a view illustrating a step coverage according to a deposition rate of a window electrode layer; and

FIGS. 11 and 12 are pictures illustrating images of a solar cell formed through a method of manufacturing solar cell module according to an embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the specification, it will be understood that when a layer (or film) is referred to as being ‘on’ another layer or substrate, it can be directly on the other layer or substrate, or intervening layers may also be present. Also, in the figures, the dimensions of layers and regions are exaggerated for clarity of illustration. Like reference numerals refer to like elements.

Additionally, the embodiment in the detailed description will be described with sectional views as ideal exemplary views of the present invention. In the figures, the dimensions of layers and regions are exaggerated for clarity of illustration. Accordingly, shapes of the exemplary views may be modified according to manufacturing techniques and/or allowable errors. Therefore, the embodiments of the present invention are not limited to the specific shape illustrated in the exemplary views, but may include other shapes that may be created according to manufacturing processes. Areas exemplified in the drawings have general properties, and are used to illustrate a specific shape of a semiconductor package region. Thus, this should not be construed as limited to the scope of the present invention. An embodiment described and exemplified herein includes a complementary embodiment thereof.

In the following description, the technical terms are used only for explaining specific embodiments while not limiting the present invention. The meaning of “include,” “comprise,” “including,” or “comprising,” specifies a property, a region, a fixed number, a step, a process, an element and/or a component but does not exclude other properties, regions, fixed numbers, steps, processes, elements and/or components.

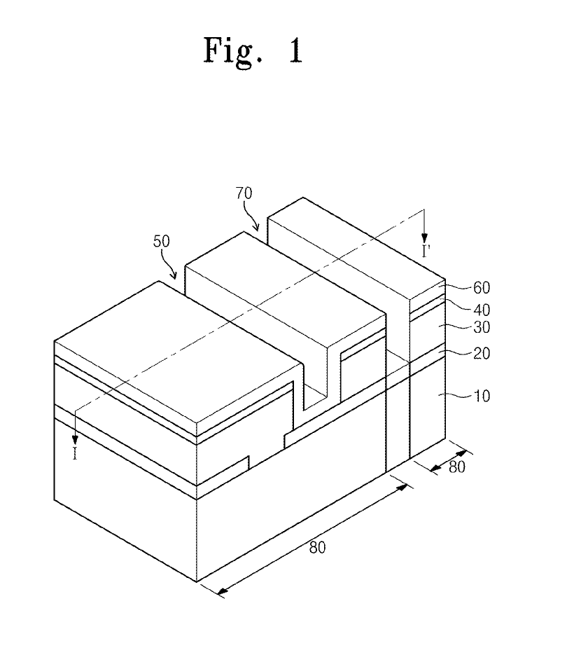

FIG. 1 is a perspective view illustrating a solar cell module according to an embodiment of the present invention.

Referring to FIG. 1, the solar cell module may include a window electrode layer 60 that extends from the top of a light absorbing layer 30 at the periphery of a first trench 50 to the bottom of the first trench 50. The window electrode layer 60 may electrically contact a bottom electrode layer 20 by the first trench 50. The window electrode layer 60 may have a thickness of about 0.1 μm to about 1.5 μm. The window electrode layer 60 may include zinc oxide or indium tin oxide doped with impurities. The window electrode layer 60 may be separated by a second trench 70.

The second trench 70 may define unit cells 80. That is, the unit cells 80 may be separately from each other by the second trench 70. The bottom electrode layer 20 may electrically connect the adjacent unit cells 80. The window electrode layer 60 may correspond to one unit cell 80 in a plane.

A method of manufacturing the above configured solar cell module according to an embodiment of the present invention will be described as follows.

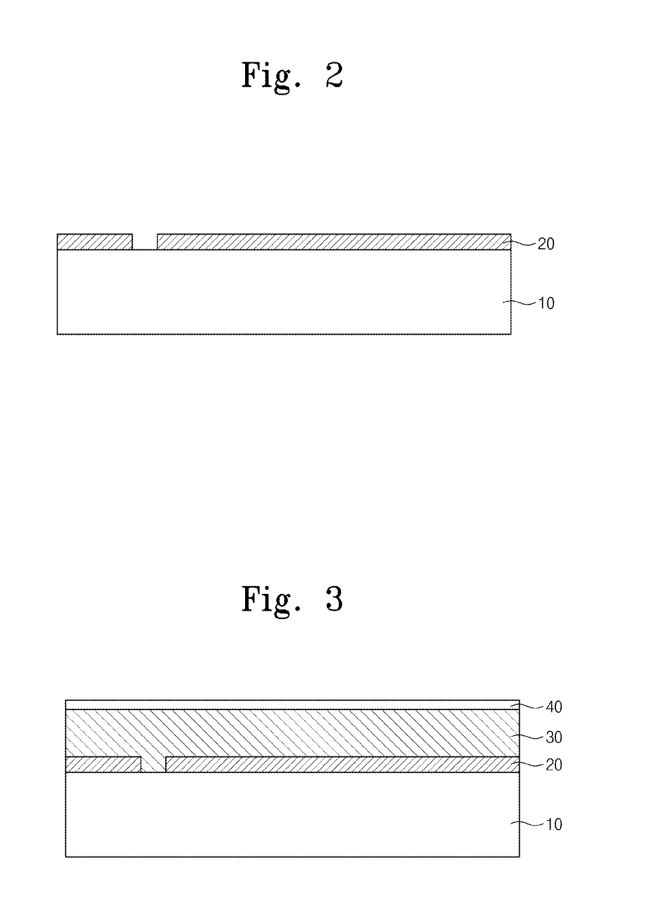

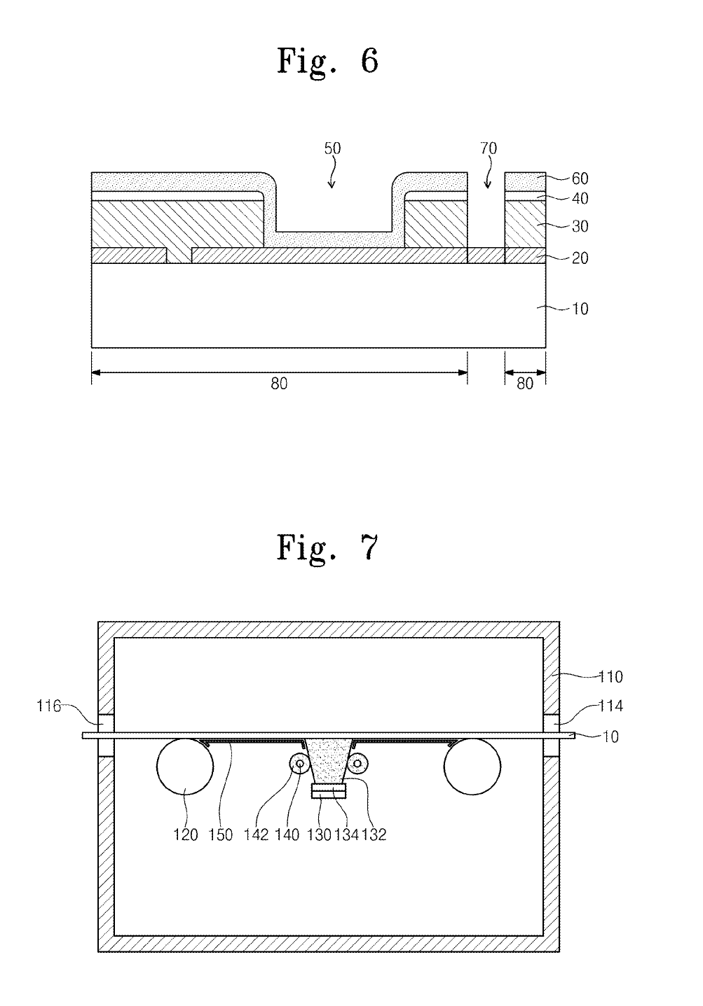

FIGS. 2 to 6 are sectional views taken along the line I-I′ of FIG. 1 illustrating a method of manufacturing a solar cell module according to an embodiment of the present invention. FIG. 7 is a sectional view illustrating an ionized physical vapor deposition apparatus for forming a window electrode layer.

Referring to FIG. 2, a bottom electrode layer is formed on a substrate 10. The substrate 10 may be a soda lime glass substrate. The substrate 10 may be a ceramic (such as alumina) substrate, a stainless steel, a metal (such as a copper tape) substrate, or a poly film. The bottom electrode layer 20 may have a low resistivity and an excellent adhesion to a glass substrate, which prevents a delamination phenomenon due to the difference in a thermal expansion coefficient. More specifically, the bottom electrode layer 20 may include a conductive metal (such as molybdenum) layer. Molybdenum may have high electrical conductivity, a formation property of ohmic contact to another thin layer, and high temperature stability under Se atmosphere. The bottom electrode layer 20 may be patterned from a conductive metal layer formed on the front of the substrate 10. The conductive metal layer may be patterned through a laser beam or photolithograph process.

Referring to FIG. 3, a light absorbing layer 30 and a buffer layer 40 are stacked on the bottom electrode layer 20. The light absorbing layer 30 may generate electricity from light energy through the photoelectric effect. The light absorbing layer 30 may include at least one chalcopyrite compound semiconductor selected from CuInSe, CuInSe₂, CuInGaSe, and CuInGaSe₂. The chalcopyrite compound semiconductor may have an energy bandgap of about 1.2 eV.

A buffer layer 40 may buffer an energy bandgap between the window electrode layer 60 of FIG. 1 and the light absorbing layer 30. The buffer layer 40 may have an energy bandgap, which is greater than that of the light absorbing layer 30 and less than that of the window electrode layer 60. For example, the buffer layer 40 may include CdS. CdS may have a uniform energy bandgap of about 2.4 eV. Although not shown in the drawings, an intrinsic layer may be formed between the buffer layer 40 and the window electrode layer 60. The intrinsic layer may include i-ZnO. i-ZnO may have the same crystal structure as the window electrode layer 60. For example, the intrinsic layer and the window electrode layer 60 may have a wurtzite crystal structure.

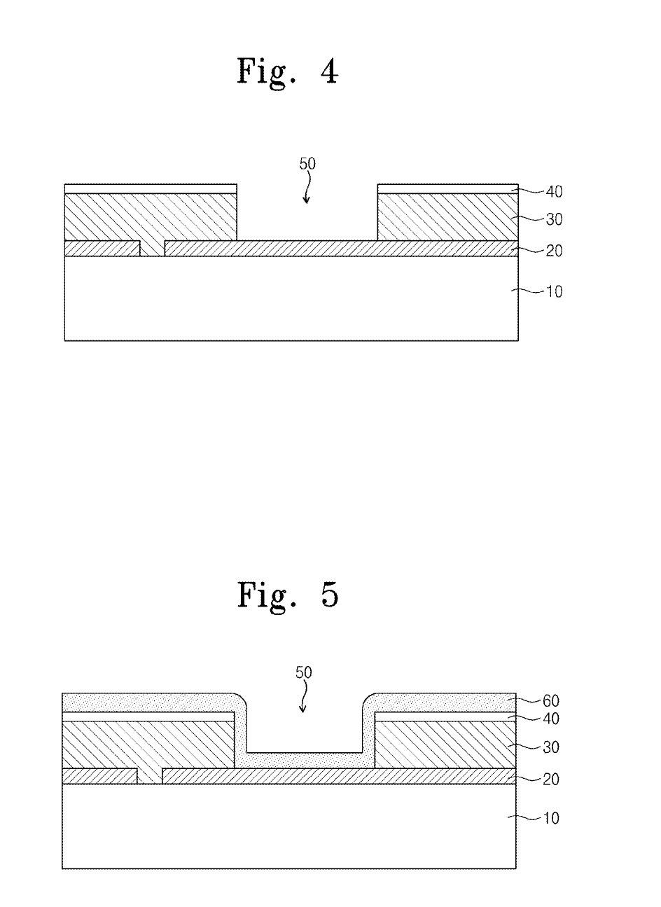

Referring to FIG. 4, a first trench is formed by partially removing the buffer layer 40 and the light absorbing layer 30. The first trench 50 may be formed by mechanical scribing to the buffer layer 40 and the light absorbing layer 20. Moreover, the first trench 50 may expose the light absorbing layer 30 to a sidewall.

Referring to FIG. 5, the window electrode layer 60 is formed on the buffer layer 40 and the bottom electrode layer 20. The window electrode layer 60 may extend from the top of the buffer layer 40 to the bottom of the first trench 50 along the sidewall of the first trench 50. The window electrode layer 60 may have a thickness of about 0.1 μm to about 1.5 μm. The window electrode layer 60 may include ZnO doped with a conductive impurity such as B, Ga, Al, Mg, In, Sn, and F. The window electrode layer 60 may include Indium Tin Oxide (ITO). The window electrode layer 60 may be formed through an Ionized Physical Vapor Deposition (IPVD) method.

Referring to FIGS. 5 and 7, an IPVD apparatus 100 may include a sputter gun 130 disposed below a substrate 10 and moving inside a chamber 110, and a plurality of inductively coupled plasma tubes 140 disposed between the sputter gun 130 and the substrate 10. The substrate 10 may be supported by rollers 120. An entering slot and an outgoing slot of the substrate 10 may be formed at the both sides of the chamber 110, respectively.

The sputter gun 130 may induce a first plasma 132 in order to sputter deposition particles from a target 134. The plurality of inductively coupled plasma tubes 140 may induce a second plasma 142 that expanses more than the first plasma 132. The second plasma 142 may uniformly mix deposition particles sputtered from the target 134. The second plasma 142 may increase an ionization rate of inert gas charged from the first plasma 312. Due to this, the window electrode layer 60 having a similar thickness may be formed on the sidewall of the trench 50 in addition to the bottom of the trench 50 and the top of the buffer layer 40. Moreover, the second plasma 142 as inductively coupled plasma may restrict an exposure area of the first plasma 132. The plurality of inductively coupled plasma tubes 140 may reduce a consumption rate of the target 134.

Accordingly, the method of manufacturing a solar cell module according to an embodiment of the present invention may increase or maximize its production yield and productivity.

Referring to FIGS. 1 to 6, the second trench 70 exposing the bottom electrode layer 20 may be formed by partially removing the window electrode layer 60 and the light absorbing layer 30 adjacent to the first trench 50. The second trench 70 separates the unit cells 80. The second trench 70 may be formed through laser beam or a scribing process using a knife. The window electrode layer 60 and the bottom electrode layer 20 may be vertically separated by the light absorbing layer 30 and the buffer layer 40 in one unit cell 80, and adjacent unit cells 80 may be connected in series. One unit cell 80 may include the stacked bottom electrode layer 20, light absorbing layer 30, and buffer layer 40, and window electrode layer 60. The unit cell 80 may be defined by the second trench 70. The window electrode layer 60 of one unit cell 80 may be connected to the bottom electrode layer 20 of another adjacent unit cell 80 through the first trench 60. As mentioned above, the window electrode layer 60 is formed through the IPVD method. The IPVD method may provide the window electrode layer 60 having a more excellent step coverage than a physical vapor deposition method or a chemical vapor deposition method.

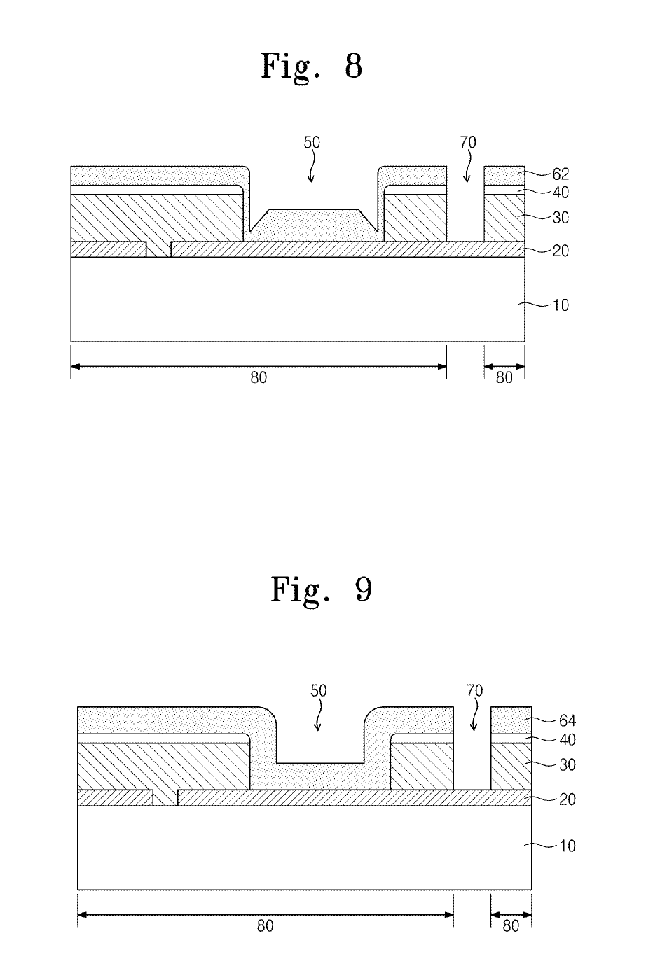

FIGS. 8 and 9 are sectional views illustrating respective second and third window electrode layers formed through a physical vapor deposition method and a chemical vapor deposition method. Here, it is described that the first window electrode layer is formed through the IPVD method.

Referring to FIG. 8, the second window electrode layer formed through a physical vapor deposition method has a thinner thickness on the sidewall than the bottom of a first trench 50. For example, when the second window electrode layer 62 is formed with a thickness of about 0.1 μm to about 1.5 μm on the top of the buffer layer 40 or the bottom of the first trench 50, it is almost not deposited on the sidewall of the first trench. The reason is that a substance to be deposited has a very high straightness. The physical vapor deposition method may include a sputtering method. The second window electrode layer 62 has a lower electrical conductivity at the sidewall of the first trench 50. Therefore, a typical physical vapor deposition method may provide the second window layer 62 having a lower step coverage. The step coverage may be defined by a thickness ratio of the first and second window electrode layers 60 and 62 on the flat top of the buffer layer 40 and the first and the sidewall of the first trench 50. For example, the first window electrode layer 60 may have a step coverage of more than about 20%. The second window electrode layer 62 may be formed with a step coverage of less than about 10%.

Referring to FIGS. 5 and 9, the third window electrode layer 64 formed through a chemical vapor deposition method may have the same thickness on the bottom and the sidewall of the first trench 50. The third window electrode layer 64 may have a high step coverage. However, the third window electrode layer 64 may have a predetermined electrical conductivity only when more than a predetermined thickness is formed from impurity such as a post reactant remaining during chemical vapor deposition. For example, the first window electrode layer 60 of about 1 μm may have the same or similar electrical resistance to the third window electrode layer 64 of more than about 3 μm. At this point, as the thickness of the third window electrode layer 64 is increased, its transmittance may be reduced. The third window electrode layer 64 may reduce the efficiency of a solar cell.

Accordingly, the first window electrode layer 60 may have more excellent electrical or optical properties than the second and third window electrode layers 62 and 64 formed through a typical physical vapor deposition method or chemical vapor deposition method.

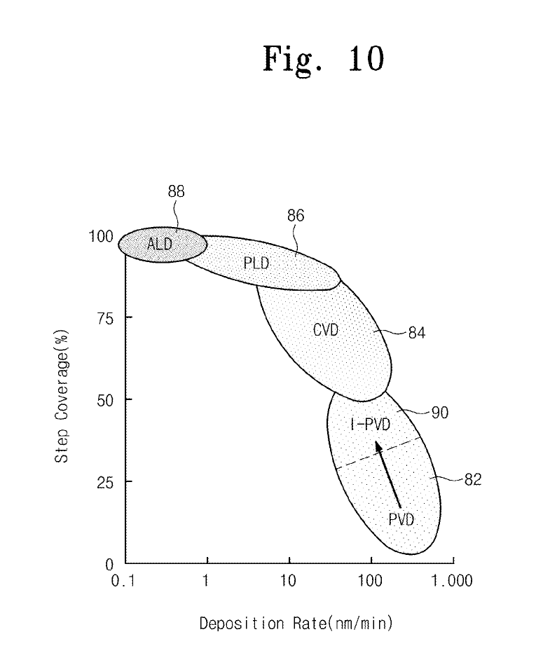

FIG. 10 is a view illustrating a step coverage according to a deposition rate of a window electrode layer. Here, an x-axis represents a deposition rate (nm/min) and a y-axis represents a step coverage %.

Referring to FIGS. 1 and 10, an IPVD method 90 may provide the window electrode layer 60 that has a higher deposition rate than a Chemical Vapor Deposition (CVD) method 84, a Pulsed Laser Deposition (PLD) method 86, and an Atomic Layer Deposition (ALD) method 88. The IPVD method 90 may provide the window electrode layer 60 having a lower step coverage than a CVD method 84, a PLD method 86, and an ALD method 88. As the deposition rate of the window electrode layer 60 becomes lower, the step coverage becomes higher. On the contrary, as the deposition rate of the window electrode layer 60 becomes higher, the step coverage becomes lower. The IPVD method 90 may provide the window electrode layer 60 having a higher step coverage than the physical vapor deposition method 82. The IPVD method 90 may form the window electrode layer 60 at a lower deposition rate than the physical vapor deposition method 82. The IPVD method 90 may provide the window electrode layer 60 having an excellent step coverage and deposition rate.

Accordingly, the method of manufacturing a solar cell module according to an embodiment of the present invention may increase or maximize its production yield and productivity.

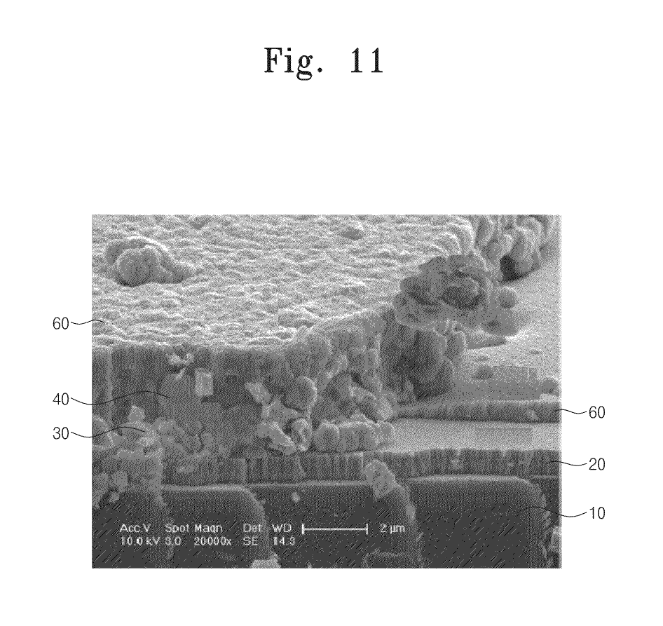

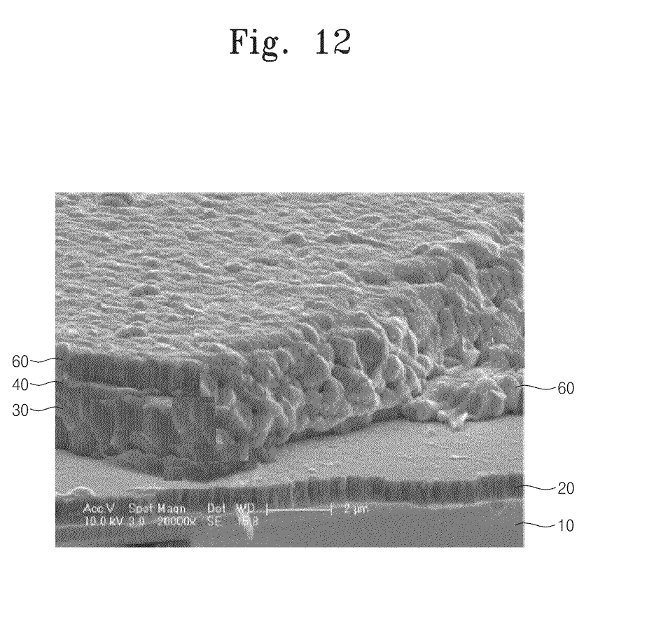

FIGS. 11 and 12 are pictures illustrating images of a solar cell formed through a method of manufacturing solar cell module according to an embodiment of the present invention.

Referring to FIGS. 11 and 12, the window electrode layer 60 may be continuously connected from the top of the buffer layer 40 to the top of the bottom electrode layer 20. The window electrode layer 60 may extend along the sidewalls of the buffer layer 40 and the light absorbing layer 30. The window electrode layer 60 may have a morphology on the sidewalls of the buffer layer 40 and the light absorbing layer 30. The window electrode layer 60 may be formed on the sidewalls of the buffer layer 40 and the light absorbing layer 30 with an excellent step coverage.

As a result, the method of manufacturing a solar cell module according to an embodiment of the present invention may increase or maximize its production yield and productivity.

According to embodiments of the present invention, a window electrode layer as a transparent conductive layer may be formed through an ionized physical vapor deposition method. The ionized physical vapor deposition method may provide a window electrode layer having more excellent step coverage then a physical vapor deposition method. Additionally, the ionized physical vapor deposition method may provide a window electrode layer having a higher electrical conductivity than a chemical vapor deposition method, and may reduce the time consumed for manufacturing the window electrode layer. Accordingly, a method of manufacturing a solar cell module according to an embodiment of the present invention may increase or maximize its production yield and productivity.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of manufacturing a solar cell module, comprising:
forming a bottom electrode layer on a substrate;
forming a light absorbing layer on the bottom electrode layer and the substrate;
forming a first trench that exposes the bottom electrode layer by patterning the light absorbing layer; and
forming a window electrode layer that extends from the top of the light absorbing layer to the bottom of the bottom of the first trench,
wherein the window electrode layer is formed through an ionized physical vapor deposition method.

2. The method of claim 1, wherein the window electrode layer comprises zinc oxide.

3. The method of claim 2, wherein the zinc oxide further comprises at least one conductive impurity of boron, gallium, aluminum, magnesium, indium, tin, and fluoride.

4. The method of claim 1, wherein the window electrode layer comprises indium tin oxide.

5. The method of claim 1, wherein the window electrode layer has a thickness of about 0.1 μm to about 1.5 μm, and has a step coverage of more than about 20% at the bottom and sidewall of the first trench.

6. The method of claim 1, wherein the ionized physical vapor deposition method uses a first plasma of inert gas that sputters deposition particles of the window electrode layer from a target and a second plasma that increases an ionization rate of the inert gas.

7. The method of claim 6, wherein the first plasma is induced from a sputter gun below the substrate, and the second plasma is induced from inductively coupled plasma tubes between the sputter gun and the substrate.

8. The method of claim 1, wherein the forming of the light absorbing layer further comprises forming a buffer layer on the light absorbing layer.

9. The method of claim 8, wherein the buffer layer comprises cadmium sulfide.

10. The method of claim 8, wherein the light absorbing comprises a chalcopyrite compound semiconductor of Copper Indium Gallium Selenide (CIGS).

11. The method of claim 1, wherein the bottom electrode layer comprises molybdenum.

12. The method of claim 1, further comprising separating cells by using a second trench that exposed the bottom electrode layer, the second trench being formed by removing the window electrode layer and the light absorbing layer adjacent to the first trench.
